(19) United States
(12) Patent Application Publication
(10) Pub. No.: US 2015/0279689 A1
(43) Pub. Date: Oct. 1, 2015

(54) METHOD FOR MANUFACTURING SEMICONDUCTOR DEVICE

(71) Applicant: KABUSHIKI KAISHA TOSHIBA, Tokyo (JP)

(72) Inventors: Hiroshi YAMAMOTO, Kuwana-shi (JP); Toshiyuki Sasaki, Yokkaichi-shi (JP); Mitsuhiro Omura, Kuwana-shi (JP)

(73) Assignee: KABUSHIKI KAISHA TOSHIBA

(21) Appl. No.: 14/453,925

(22) Filed: Aug. 7, 2014

(30) Foreign Application Priority Data
Mar. 25, 2014 (JP) 2014-062668

(51) Int. Cl. H01L 21/311

(52) U.S. Cl. CPC H01L 21/31144; H01L 21/31116

(57) ABSTRACT

According to one embodiment, a method for manufacturing semiconductor device includes: forming a mask layer on a layer to be used as an etching object, the mask layer having a first surface and a second surface, a first hole or trench being provided to pierce the mask layer; forming a second hole or trench in the layer by etching the layer exposed from the first hole or trench, and forming an eave portion on a side wall of the first hole or trench to make an opening of the first hole or trench narrow without plugging the first hole or trench; and supplying an etching gas including obliquely-incident ions into the second hole or trench under the cave portion, and etching a side wall of the second hole or trench with the etching gas.

15

### CROSS-REFERENCE TO RELATED APPLICATIONS

This application is based upon and claims the benefit of priority from Japanese Patent Application No.2014-062668, filed on Mar. 25, 2014; the entire contents of which are incorporated herein by reference.

### FIELD

Embodiments described herein relate generally to a method for manufacturing semiconductor device.

### BACKGROUND

Plasma processing is used to manufacture a semiconductor device. Plasma processing is a method in which a substrate (e.g., a semiconductor wafer) or a film provided on the substrate is processed by generating plasma and causing ions inside the plasma to be incident on the substrate or the film. In the manufacturing process of the semiconductor device, holes or trenches are formed in the substrate or the film by etching the substrate or the film with the ions that are incident. In the manufacturing process of the semiconductor device, precise control of the patterned configuration is necessary to ensure the electrical performance of the semiconductor device. For example, perpendicular patterning of the via hole side walls or the trench side walls is necessary.

However, the aspect ratios of the holes or trenches are increasing; and there are cases where precise control of the patterned configuration is not possible because etching (side etching) of the side walls of the holes or trenches occurs when the ions reach the side walls of the holes or trenches by being obliquely incident inside the holes and inside the trenches.

### BRIEF DESCRIPTION OF THE DRAWINGS

FIG. 1 is a flowchart showing a method for manufacturing a semiconductor device according to an embodiment;

FIG. 2A is a schematic cross-sectional view showing the method for manufacturing the semiconductor device according to the embodiment and FIG. 2B is a schematic plan view showing the method for manufacturing the semiconductor device according to the embodiment;

FIG. 3 to FIG. 6 are schematic cross-sectional views showing the method for manufacturing the semiconductor device according to the embodiment;

FIG. 7 is a schematic cross-sectional view showing a method for manufacturing a semiconductor device according to a reference example;

FIG. 8A is a schematic cross-sectional view showing a method for manufacturing the semiconductor device according to a modification of the embodiment and FIG. 8B is a schematic plan view showing the method for manufacturing the semiconductor device according to the modification of the embodiment;

FIG. 9A to FIG. 9C are schematic cross-sectional views showing the method for manufacturing the semiconductor device according to the modification of the embodiment;

FIG. 10 is a schematic configuration diagram of the plasma processing apparatus according to the embodiment;

FIG. 11 is a perspective view showing a substrate electrode according to the embodiment;

FIG. 12 shows a voltage waveform (with a phase difference of π/2) applied an electrode element according to the embodiment;

FIG. 13 is a schematic view showing ions incident on a sample according to the embodiment; and

FIG. 14A and FIG. 14B are schematic views showing states in which side walls of trenches and holes according to the embodiment are patterned.

### DETAILED DESCRIPTION

In general, according to one embodiment, a method for manufacturing semiconductor device includes: forming a mask layer on a layer to be used as an etching object, the mask layer having a first surface and a second surface, the second surface being on a side opposite to the first surface, a first hole or a first trench being provided to pierce the mask layer from the first surface to the second surface; forming a second hole or a second trench in the layer by etching the layer exposed from the first hole or the first trench, and forming an eave portion on a side wall of the first hole or a side wall of the first trench to make an opening of the first hole or first trench narrow without plugging the first hole or the first trench; and supplying an etching gas including obliquely-incident ions into the second hole or into the second trench under the cave portion, and etching a side wall of the second hole or a side wall of the second trench with the etching gas.

Embodiments will now be described with reference to the drawings. In the description hereinbelow, similar members are marked with like reference numerals, and a description is omitted as appropriate for members once described.

In the embodiment, hole patterning and trench patterning are performed using a plasma processing apparatus in which perpendicular patterning of the hole side wall and the trench side wall is possible. In the plasma processing apparatus, ions inside the plasma can be caused to be obliquely incident inside the hole and inside the trench. The details of the plasma processing apparatus are described below. First, the method for manufacturing the semiconductor device according to the embodiment will be described.

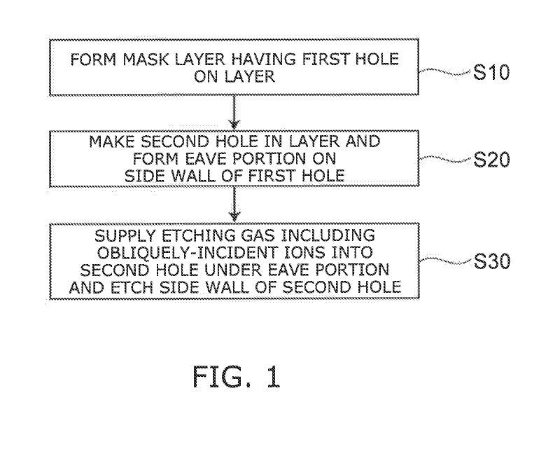

FIG. 1 is a flowchart showing the method for manufacturing the semiconductor device according to the embodiment,

In the embodiment, first, a mask layer is formed on a layer to be used as an etching object, where the mask layer has a front surface and a back surface on the side opposite to the front surface, and a first hole is provided to pierce the mask layer from the front surface to the back surface (step S10).

Then, a second hole is formed in the layer recited above by etching the layer where the layer is exposed from the first hole, and an eave portion is formed on the side wall of the first hole to make the opening of the first hole narrow without plugging the first hole (step S20).

Continuing, an etching gas including obliquely-incident ions is supplied to the second hole under the eave portion, and the side wall of the second hole is etched by the etching gas (step S30).

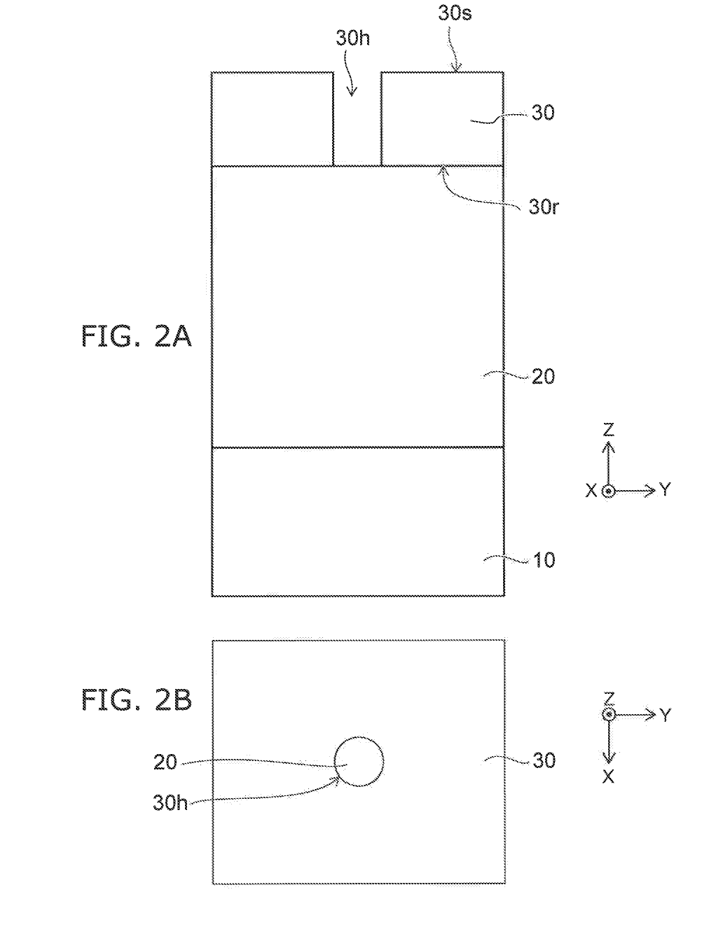

A specific example of the flow of FIG. 1 is described using FIG. 2A to FIG. 6.

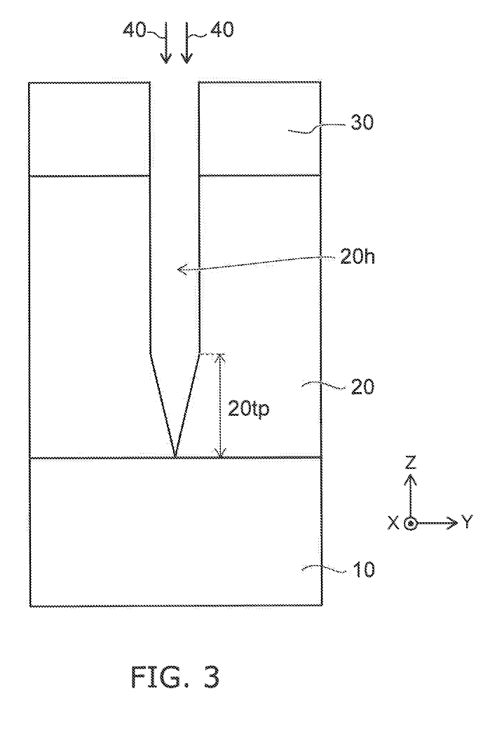

FIG. 2A is a schematic cross-sectional view showing the method for manufacturing the semiconductor device according to the embodiment; FIG. 2B is a schematic plan view showing the method for manufacturing the semiconductor device according to the embodiment; and FIG. 3 to FIG. 6 are schematic cross-sectional views showing the method for manufacturing the semiconductor device according to the embodiment. In the embodiment, an XYZ coordinate system is introduced to the drawings.

As shown in FIG. 2A, a layer 20 is formed on a foundation 10. Continuing, a mask layer 30 is formed on the layer 20. The mask layer 30 has a front surface 30s, and a back surface 30r on the side opposite to the front surface 30s. A hole 30h is provided in the mask layer 30 to pierce the mask layer 30 from the front surface 30s to the back surface 30r. The exterior form of the hole 30h when the mask layer 30 is viewed from the upper surface is, for example, circular. The exterior form of the hole 30h when the mask layer 30 is viewed from the upper surface is not limited to a circle and includes rectangles such as quadrilaterals.

Here, the foundation 10 is a semiconductor substrate, an insulating layer, etc. The layer 20 includes a semiconductor layer or an insulating layer. The layer 20 is, for example, a layer in which a conductive layer and an insulating layer are stacked alternately in the Z-direction of the drawings, a layer including silicon oxide and silicon nitride, etc. The material of the mask layer 30 is carbon (C), silicon oxide (SiO₂), etc. The material of the mask layer 30 is selected so that the etching rate of the material is slower than that of the layer 20 under the mask layer 30.

Then, as shown in FIG. 3, the layer 20 that is exposed from the hole 30h is etched. The etching is, for example, RIE (Reactive Ion Etching). Thereby, a hole 20h is formed in the layer 20. Here, the value of the ratio of the depth of the hole 20h to the inner diameter of the hole 20h (the aspect ratio) is 10 or more. In the RIE, ions that travel parallel to the

Z-direction from the layer 20 toward the mask layer 30 are caused to be incident inside the hole 30h. In the drawing, arrows 40 illustrate the state of the ions traveling inside the etching gas. This is called the ions 40. The etching gas is, for example, a gas including carbon (C) and fluorine (F) such as CHF₃ or the like, hydrogen bromide (HBr), oxygen (O₂), etc.

After the etching, the lower portion of the hole 20h has a tapered configuration in which the diameter decreases toward the foundation 10. The portion of the hole 20h having the tapered configuration is called a tapered portion 20tp. It is considered that the tapered portion 20tp is formed because, for example, the amount of the ions (the etchant) traveling parallel to the Z-direction is insufficient at the lower portion of the hole 20h which has a large aspect ratio, components of the etched layer 20 re-adhere to the lower portion of the hole 20h which has the large aspect ratio, etc.

After forming the hole 20h, the supply of the etching gas that etches the layer 20 is stopped.

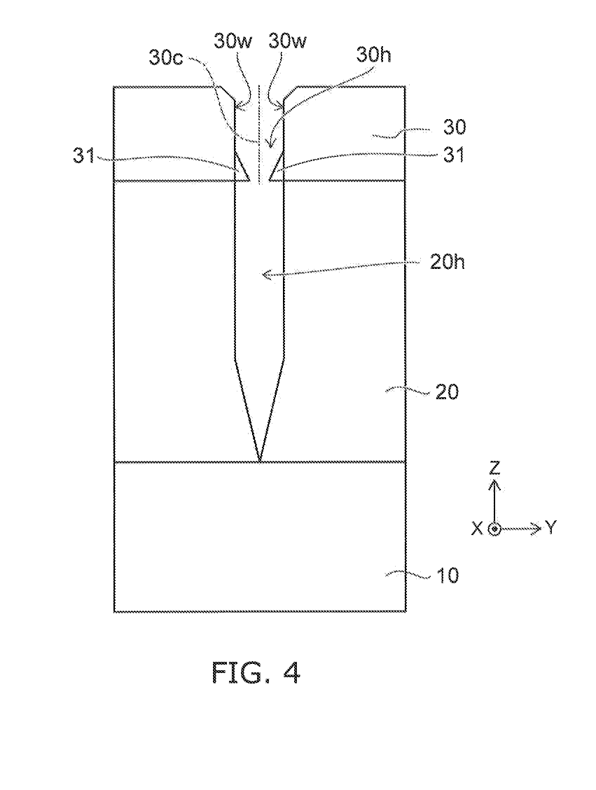

Then, as shown in FIG. 4, an eave portion 31 that protrudes from a side wall 30w of the hole 30h toward a central axis 30c of the hole 30h is formed on the side wall 30w without plugging the hole 30h. The eave portion 31 is formed by etching a portion of the mask layer 30 so that components of the etched mask layer 30 are re-adhered to the side wall 30w of the hole 30h. The gas for etching the mask layer 30 is selected so that the etching rate of the mask layer 30 is faster than the etching rate of the layer 20.

Further, in the etching of the mask layer 30, the etching progresses at conditions so that physical etching rather than chemical etching is dominant. The physical etching is, for example, sputtering, etc. The etching gas used in the physical etching is a noble gas such as argon (Ar) or the like. The etching gases used in a condition that physical etching is dominant by suppressing chemical etching are a gas mixture of carbonyl sulfide (COS) and oxygen (O₂), nitrogen (N₂), etc.

For example, in the case where the mask layer 30 includes carbon, a plasma gas including carbonyl sulfide (COS) and oxygen (O₂) is selected as the etching gas to etch the mask layer 30. By using such a plasma gas, the mask layer 30 is etched at conditions so that physical etching is more dominant than chemical etching.

In the process of forming the eave portion 31, a height L of the eave portion 31 from the side wall 30w of the hole 30h is controlled as follows.

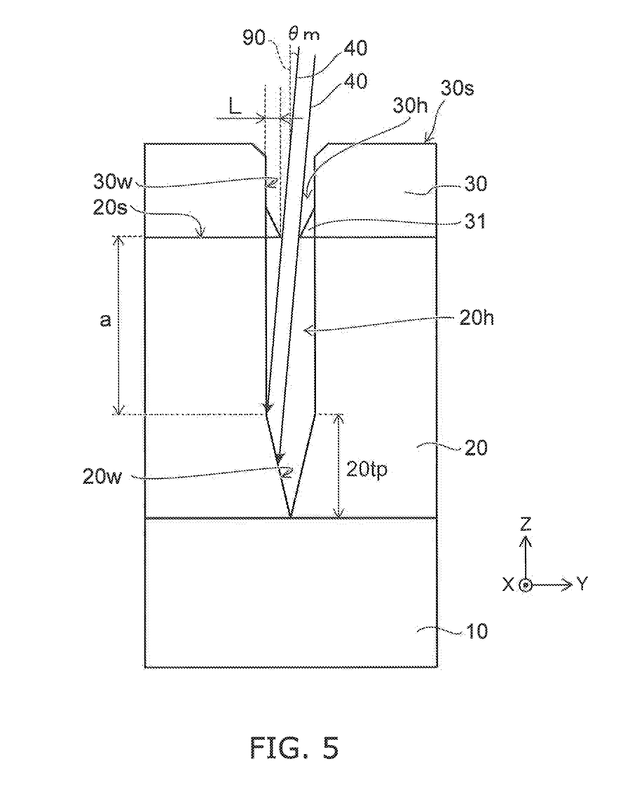

For example, in step S30 shown in FIG. 1, a maximum angle θm is the maximum angle at which the ions 40 tilt from a normal 90 that is perpendicular to the front surface 30s of the mask layer 30 shown in FIG. 5. The maximum angle θm is, for example, 1° to 10°.

The minimum distance “a” is the minimum distance between a front surface 20s of the layer 20 and the position where a side wall 20w of the hole 20h is etched by the obliquely-incident ions. In the embodiment, the destination is to etch the side wall 20w of the tapered portion 20tp of the hole 20h so that the hole 20h ultimately has a perpendicular configuration, Therefore, the minimum distance “a” is the distance from the front surface 20s of the layer 20 to the upper portion of the tapered portion 20tp. Then, the height L of the eave portion 31 is controlled to satisfy the formula tan(θm)=L/a by adjusting the bias power applied to the plasma gas.

The growth rate of the eave portion 31 increases as the ion energy inside the plasma gas is increased. For example, the growth rate of the cave portion 31 increases as the bias power applied to the plasma gas is increased. For example, the eave portion 31 that has the predetermined height L is formed by adjusting the power of the high frequency voltage (the pulse bias) applied to the plasma gas to be in a range of 200 W or more. Here, the frequency of the pulse bias is 13 MHz.

In the method described above, the cave portion 31 may be formed by a method in which the cave portion 31 is formed by etching the mask layer 30 after forming the hole 20h in the layer 20; or the cave portion 31 may be formed when forming the hole 20h in the layer 20.

As described above, the material of the mask layer 30 is selected so that the etching rate of the material is slower than that of the layer 20 under the mask layer 30. However, when forming the hole 20h in the layer 20 by RIE, a portion of the mask layer 30 also is etched. The eave portion 31 may be formed by causing components of the etched mask layer 30 to re-adhere to the side wail 30w of the mask layer 30.

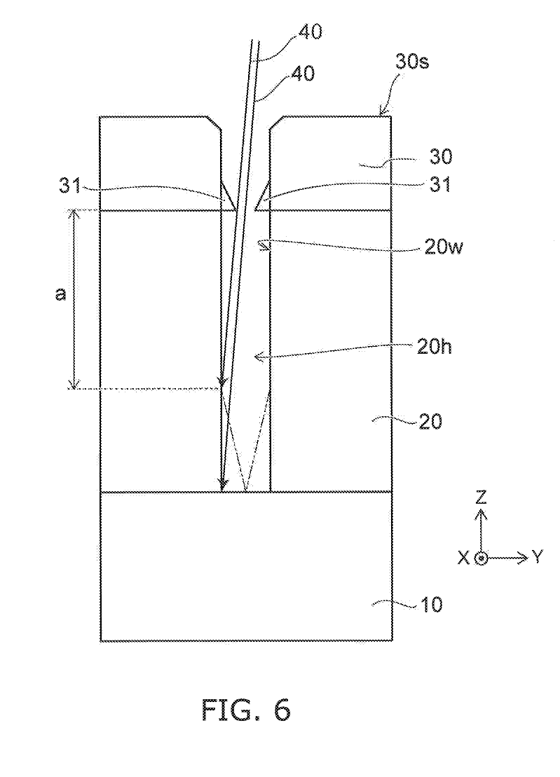

Then, as shown in FIG. 6, an etching gas is supplied to the hole 20h under the cave portion 31. The etching gas includes the ions 40 that are obliquely incident. Accordingly, the side wall 20w of the tapered portion 20tp is etched by the ions 40 being irradiated onto the side wall 20w of the tapered portion 20tp of the hole 20h. However, the ions 40 are not irradiated onto the portion of the side wall 20w illustrated by the distance “a” due to the shielding effect of the eave portion 31.

Here, the maximum angle Om is the maximum angle of the tilt of the ions 40. Accordingly, the ions 40 that are incident at an angle θ that is smaller than the maximum angle θm also are included inside the etching gas. Although the state of the ions 40 being tilted from the normal 90 toward the right side is shown in FIGS. 5 and 6, the ions 40 that tilt from the normal 90 toward the left side also exist. Further, the plasma processing apparatus may rotate the foundation 10, the layer 20, and the mask layer 30 (described below).

Accordingly, the ions 40 are irradiated onto the entire region of the side wall 20w of the tapered portion 20tp; and the configuration of the final hole 20h after the etching is a perpendicular configuration as in FIG. 6. Subsequently, the eave portion 31 is removed by, for example, etching.

### REFERENCE EXAMPLE

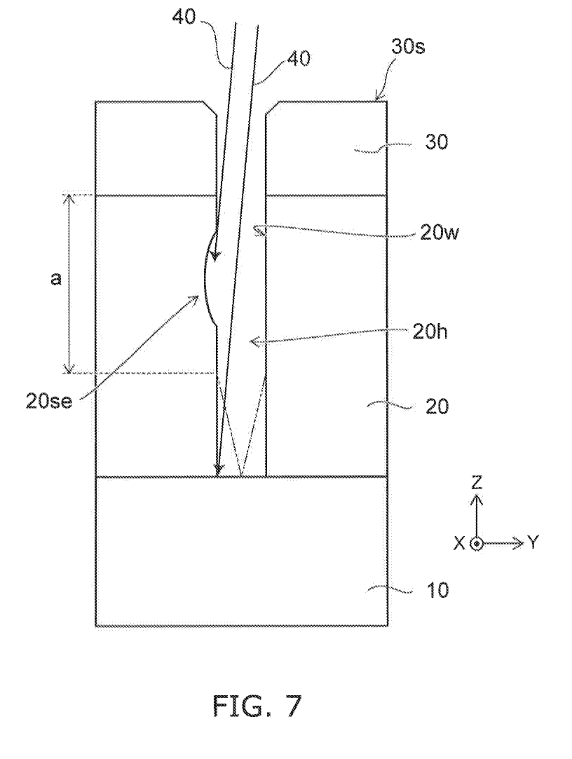

FIG. 7 is a schematic cross-sectional view showing a method for manufacturing the semiconductor device according to a reference example.

As in FIG. 7, when the etching gas is supplied to the hole 20h in the case where the eave portion 31 is not provided, the ions 40 that are obliquely incident are irradiated onto the portion of the side wall 20w illustrated by the distance “a”.

Thereby, side etching of the side wall 20w of the hole 20h occurs as illustrated by arrow 20se.

Conversely, in the embodiment, by providing the eave portion 31, the ions 40 are not irradiated onto the portion of the side wall 20w illustrated by the distance “a”. Thereby, the side etching of the side wall 20w of the hole 20h does not occur; the side wall 20w of the tapered portion 20tp is etched; and the hole 20h having a perpendicular configuration is formed.

### Modification

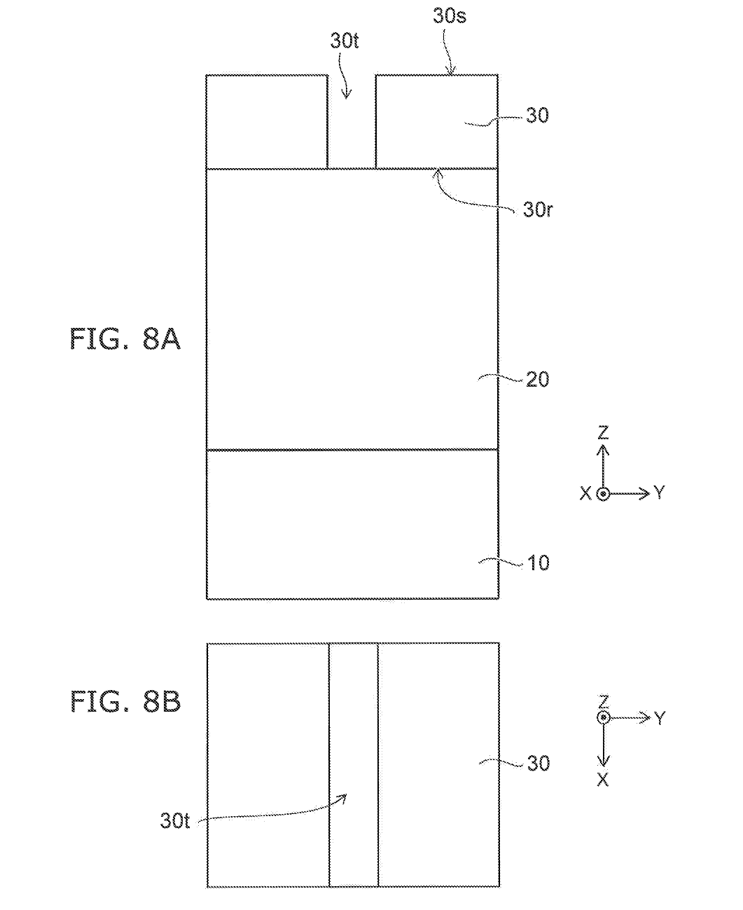

FIG. 8A is a schematic cross-sectional view showing a method for manufacturing the semiconductor device according to a modification of the embodiment; and FIG. 8B is a schematic plan view showing the method for manufacturing the semiconductor device according to the modification of the embodiment.

As shown in FIG. 8A and FIG. 8B, instead of the hole 30h, a trench 30t may be formed in the mask layer 30 formed on the layer 20. The trench 30t pierces the mask layer 30 from the front surface 30s to the back surface 30r. The trench 30t extends in, for example, in the X-direction.

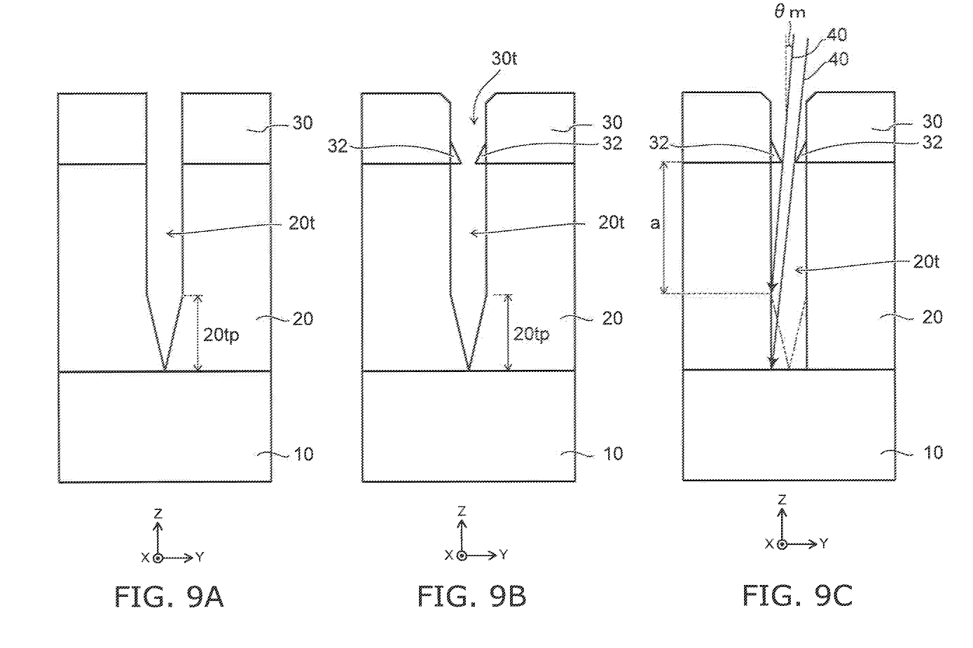

FIG. 9A to FIG. 9C are schematic cross-sectional views showing the method for manufacturing the semiconductor device according to the modification of the embodiment.

As shown in FIG. 9A, a trench 20t is formed in the layer 20 by etching the layer 20 exposed from the trench 30t.

Then, as shown in FIG. 9B, an eave portion 32 is formed on the side wall of the trench 30t to cause the width (the opening) of the trench 30t from the side wall 30w of the trench 30t to be narrow without plugging the trench 30t. The cave portion 32 extends in the X-direction.

Continuing as shown in FIG. 9C, an etching gas including obliquely-incident ions is supplied to the trench 20t under the cave portion 32; and the side wall 20w of the trench 20t is etched by the etching gas. Here, although the state of the ions 40 tilted from the normal toward the right side are shown in FIG. 9C, the ions 40 that tilt from the normal toward the left side also exist (described below). Accordingly, the ions 40 are irradiated onto the entire region of the side wall 20w of the tapered portion 20tp; and the configuration of the final trench 20t after the etching is a perpendicular configuration. Subsequently, the cave portion 32 is removed by, for example, etching.

### Plasma Processing Apparatus

A plasma processing apparatus according to the embodiment will now be described.

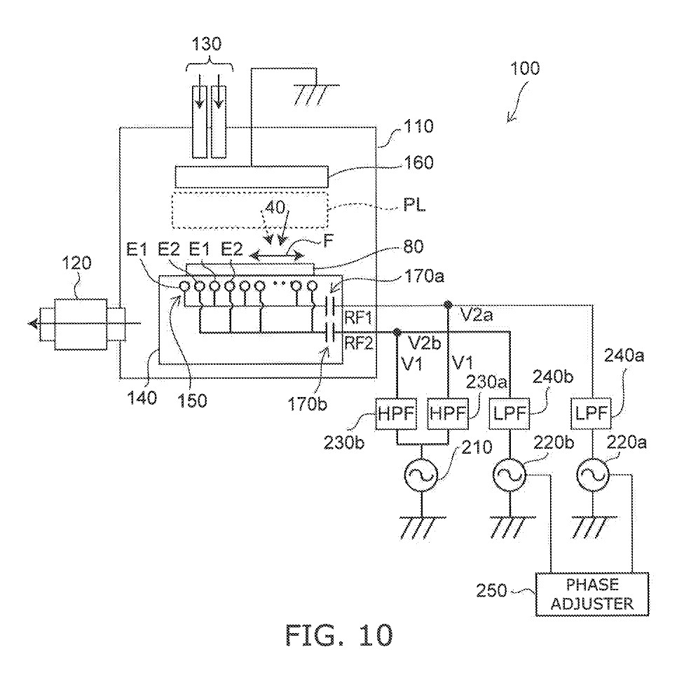

FIG. 10 is a schematic configuration diagram of the plasma processing apparatus according to the embodiment.

The plasma processing apparatus 100 is a parallel plate-type RIE (Reactive Ion Etching) apparatus.

The plasma processing apparatus 100 can form a hole, a trench, an cave portion, etc., by etching a sample 80 including a semiconductor substrate by causing the ions 40 inside plasma PL to be incident on the sample 80.

The plasma processing apparatus 100 includes a chamber 110, an exhaust port 120, a process gas supply pipe 130, a susceptor 140, a substrate electrode 150, an opposing electrode 160, capacitances 170a and 170b, an RF high frequency power supply 210, RF low frequency power supplies 220a and 220b, filters 230a, 230b, 240a, and 240b, and a phase adjuster 250. The susceptor 140 can rotate; and the sample 80 rotates due to the rotation of the susceptor 140.

The chamber 110 is an etching processing chamber in which the etching of the sample 80 is performed. The exhaust port 120 is connected to a not-shown pressure regulating valve and a not-shown evacuation pump. The gas inside the chamber 110 is evacuated from the exhaust port 120; and the interior of the chamber 110 is maintained as a high vacuum. In the case where a process gas is introduced from the process gas supply pipe 130, the flow rate of the gas flowing in from the process gas supply pipe 130 and the flow rate of the gas flowing out from the exhaust port 120 balance; and the pressure of the chamber 110 is maintained to be substantially constant.

The process gas supply pipe 130 introduces the process gas for processing the sample 80 into the chamber 110. The process gas is used to form the plasma PL. The process gas is ionized to generate the plasma PL by electro-discharge; and the ions 40 inside the plasma PL are used to etch the sample 80.

The susceptor 140 is a holder that holds the sample 80. The substrate electrode 150 is disposed in the susceptor 140 and is an electrode having a substantially flat plate configuration having an upper surface that contacts or is proximal to the lower surface of the sample 80.

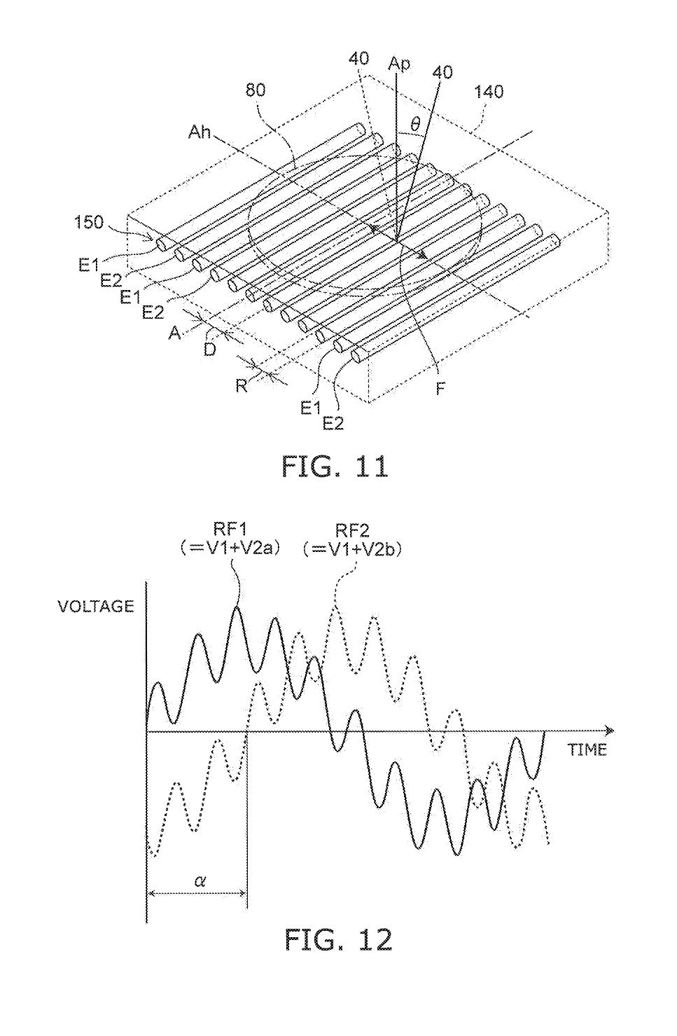

FIG. 11 is a perspective view showing the substrate electrode according to the embodiment.

The substrate electrode 150 is a segmented electrode that is subdivided into a plurality and includes two groups of electrode elements E1 and E2 that are disposed alternately. The two groups of electrode elements E1 and E2 are disposed substantially parallel to each other at a spacing D (the distance between the central axes); and each has a substantially circular columnar configuration having a diameter R and a central axis aligned with an axis direction A.

An RF high frequency voltage V1 and RF low frequency voltages V2a and V2b are applied to the substrate electrode 150 from the RF high frequency power supply 210 and the RF low frequency power supplies 220a and 220b. A voltage waveform RF1 in which the RF high frequency voltage V1 and the RF low frequency voltage V2a are superimposed is applied to the electrode element E1. A voltage waveform RF2 in which the RF high frequency voltage V1 and the RF low frequency voltage V2b are superimposed is applied to the electrode element E2.

The RF high frequency voltage V1 is applied to both the electrode elements E1 and E2 and is a high frequency wave alternating current voltage used to generate the plasma PL. The RF low frequency voltages V2a and V2b are applied respectively to the electrode elements E1 and E2 and are low frequency wave alternating current voltages used to attract the ions 40 from the plasma PL.

The opposing electrode 160 (FIG. 10) has the ground potential and is disposed to face the substrate electrode 150 inside the chamber 110. Parallel-plate electrodes, i.e., the opposing electrode 160 and the substrate electrode 150, are provided in the plasma processing apparatus 100.

The capacitances 170a and 170b are the combined capacitances on the path to the sample 80 from the RF high frequency power supply 210 and the RF low frequency power supplies 220a and 220b.

The RF high frequency power supply 210 generates the RF high frequency voltage V1 that is applied to the substrate electrode 150. A frequency “fh” of the RF high frequency voltage V1 is 10 MHz to 1000 MHz.

The RF low frequency power supplies 220a and 220b generate the RF low frequency voltages V2a and V2b that are applied to the substrate electrode 150. A frequency “fl ” of the RF low frequency voltages V2a and V2b is not less than 0.1 MHz and not more than 20 MHz. The RF low frequency voltages V2a and V2b have substantially the same frequency and have a phase difference a (e.g., π/2 or π). The frequency “fh” and the frequency “fl” are controlled not to be the same frequency.

The impedance between the plasma PL and the RF high frequency power supply 210 and between the plasma PL and the RF low frequency power supplies 220a and 220b is matched by a not-shown matching unit.

Here, the RF high frequency voltage V1 is expressed by the formula V1/=V01·sin(2π·fh·t); the RF low frequency voltage V2a is expressed by the formula V2a=V02·sin(2π·fl·t); and the RF low frequency voltage V2b is expressed by V2b V02·sin(2π·fl·t+α).

The filters 230a and 230b (HPFs (High Pass Filters)) prevent the RF low frequency voltages V2a and V2b from being input to the RF high frequency power supply 210 from the RF low frequency power supplies 220a and 220b. The filters 240a and 240b (LPFs (Low Pass Filters)) prevent the RF high frequency voltage V1 from being input to the RF low frequency power supplies 220a and 220b from the RF high frequency power supply 210.

The phase adjuster 250 adjusts the RF low frequency voltages V2a and V2b from the RF low frequency power supplies 220a and 220b to have the phase difference α. The high frequency wave waveform is not limited to a sine wave; and a pulse bias may be used.

FIG. 12 shows the voltage waveform (with a phase difference of π/2) applied the electrode element according to the embodiment.

The RF low frequency voltages V2a and V2b are applied to the electrode elements E1 and E2 (the substrate electrode 150). By applying the RF low frequency voltages V2a and V2b between the substrate electrode 150 and the opposing electrode 160, an electric field (a perpendicular electric field) is created in a direction Ap (referring to FIG. 11) perpendicular to the surface of the substrate electrode 150 (the sample 80). As a result, the ions 40 inside the plasma PL are attracted to the substrate electrode 150 (the sample 80).

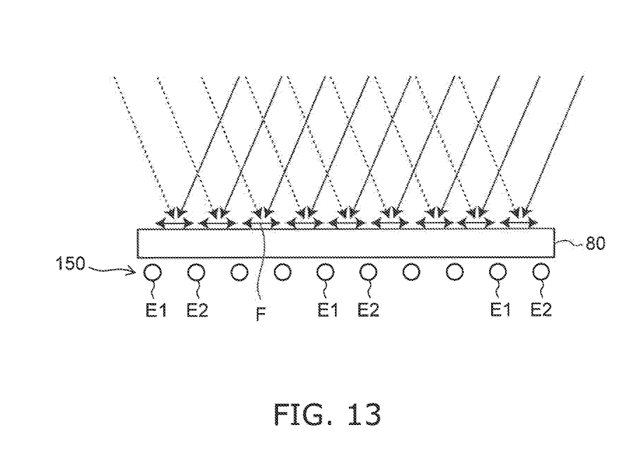

Here, the RF low frequency voltages V2a and V2b that are applied to the electrode elements E1 and E2 have the phase difference α. Therefore, in addition to the perpendicular electric field, an electric field F is generated in a direction parallel to a direction Ah parallel to the surface of the substrate electrode 150 (the sample 80) and orthogonal to the axis direction A of the electrode elements E1 and E2 (referring to FIG. 13 described below). As a result, the ions 40 follow the electric field F to be incident at the incident angle 0 (obliquely) with respect to the perpendicular direction. Due to the obliquely-incident ions 40, high-precision etching of the sample 80 is possible.

The electric field F oscillates according to the period of the RF low frequency voltages V2a and V2b. As a result, the incident angle θ of the ions 40 oscillates periodically according to the period of the RF low frequency voltages V2a and V2b.

Thus, the ions are incident on the sample 80 along the axis direction A so that the incident angle θ is alternately in the positive direction and in the negative direction. That is, in the embodiment, the ions 40 can be obliquely incident on the sample 80 at the incident angle θ.

### Operation of Plasma Processing Apparatus

FIG. 13 is a schematic view showing the ions incident on the sample according to the embodiment.

The sample 80 is transferred by a not-shown transfer mechanism into the chamber 110 in which vacuuming is performed to reach a prescribed pressure (e.g., 0.01 Pa or less). Then, the sample 80 is held by the susceptor 140.

Then, the process gas for processing the sample 80 is introduced from the process gas supply pipe 130. At this time, the process gas that is introduced to the interior of the chamber 110 is evacuated from the exhaust port 120 by a not-shown pressure regulating valve and a not-shown evacuation pump at a prescribed rate. As a result, the pressure inside the chamber 110 is maintained to be substantially constant (e.g., about 1.0 to 6.0 Pa).

Continuing, the RF high frequency voltage V1 and the RF low frequency voltages V2a and V2b are applied to the substrate electrode 150 from the RF high frequency power supply 210 and the RF low frequency power supplies 220a and 220b. The voltage waveform RF1 in which the RF high frequency voltage V1 and the RF low frequency voltage V2a are superimposed is applied to the electrode element E1. The voltage waveform RF2 in which the RF high frequency voltage V1 and the RF low frequency voltage V2b are superimposed is applied to the electrode element E2.

The density of the plasma PL is controlled by the RF high frequency voltage V1 from the RF high frequency power supply 210. The incident energy of the ions 40 incident on the sample 80 is controlled by the RF low frequency voltages V2a and V2b from the RF low frequency power supplies 220a and 220b. The sample 80 is etched by the ions 40.

The RF low frequency voltages V2a and V2b are applied to the electrode elements E1 and E2 (the substrate electrode 150). By applying the RF low frequency voltages V2a and V2b between the substrate electrode 150 and the opposing electrode 160, a perpendicular electric field is generated in the direction Ap perpendicular to the surface of the substrate electrode 150 (the sample 80) (referring to FIG. 10). As a result, the ions 40 that are inside the plasma PL are attracted to the substrate electrode 150 (the sample 80).

Here, the RF low frequency voltages V2a and V2b that are applied to the electrode elements E1 and E2 have the phase difference α. Therefore, in addition to the perpendicular electric field, the electric field F is generated in a direction parallel to the direction Ah that is parallel to the surface of the substrate electrode 150 (the sample 80) and orthogonal to the axis direction A of the electrode elements E1 and E2 (referring to FIG. 11). As a result, the ions 40 follow the electric field F to be incident at the incident angle θ with respect to the perpendicular direction.

The electric field F oscillates according to the period of the RF low frequency voltages V2a and V2b. As a result, the incident angle 0 of the ions 40 oscillates periodically according to the period of the RF low frequency voltages V2a and V2b. Thus, the ions are incident on the sample 80 along the axis direction A so that the incident angle θ is alternately in the positive direction and in the negative direction.

The oscillation of the ions 40 can be stopped by controlling the phase adjuster 250 so that the RF low frequency voltages V2a and V2b from the RF low frequency power supplies 220a and 220b are applied without a phase difference. That is, the plasma processing apparatus 100 also can perform normal RIE in which the ions 40 are incident substantially perpendicularly. In other words, the process shown in FIG. 3 to FIG. 6 can be performed inside the same etching processing chamber. Thereby, the throughput of the semiconductor device manufacturing increases.

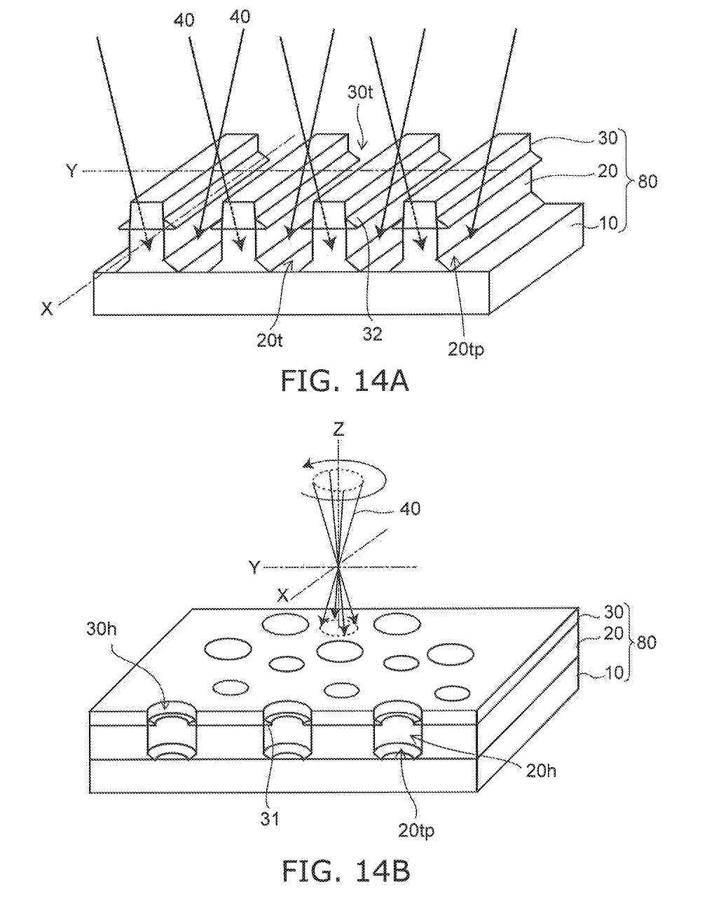

FIG. 14A and FIG. 14B are schematic views showing states in which the side walls of the trenches and holes according to the embodiment are patterned.

As shown in FIG. 14A and FIG. 14B, the sample 80 includes the foundation 10, the layer 20, and the mask layer 30. The layer 20 is formed on the foundation 10; and the mask layer 30 is formed on the layer 20.

The multiple trenches 30t are provided along the X-axis in the mask layer 30 shown in FIG. 14A. The multiple holes 30h are provided in the mask layer 30 shown in FIG. 14B.

Here, in FIG. 14A, the sample 80 does not rotate. On the other hand, in FIG. 14B, the sample 80 is rotating. In FIG. 14A and FIG. 14B, the X-axis matches the direction in which the electrode elements E1 and E2 shown in FIG. 11 extend.

In FIG. 14A, the incident angle θ (−7.5°≦θ≦7.5°) of the ions 40 changes around the X-axis as a rotational axis. As a result, the ions 40 are incident on the side wall of the tapered portion 20tp of the trench 20t. Here, the values of the incident angle θ are exemplary and are not limited to these values. In FIG. 14B, the sample 80 is rotated; and the incident angle of the ions 40 is symmetric about the Y-axis and the X-axis. That is, the ions 40 are obliquely incident from all directions; and the side wall of the tapered portion 20tp of the hole 20h is etched from all directions. Specifically, when supplying the etching gas including the obliquely-incident ions, the holder (the susceptor 140) that holds the etching object is rotated; and the side wall of the hole 20h is etched by the etching gas from all directions. On the other hand, in FIG. 14A, when supplying the etching gas including the obliquely-incident ions, the holder (the susceptor 140) that holds the etching object is fixed; and the etching by the etching gas is performed along one direction.

Thus, according to the embodiment, a hole and a trench that have perpendicular configurations in which side etching is suppressed can be made by combining normal RIE, the formation of the eave portion, and RIE using oblique ions.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, comprising:
forming a mask layer on a layer to be used as an etching object, the mask layer having a first surface and a second surface, the second surface being on a side opposite to the first surface, a first hole or a first trench being provided to pierce the mask layer from the first surface to the second surface;
forming a second hole or a second trench in the layer by etching the layer exposed from the first hole or the first trench, and forming an eave portion on a side wall of the first hole or a side wall of the first trench to make an opening of the first hole or first trench narrow without plugging the first hole or the first trench; and
supplying an etching gas including obliquely-incident ions into the second hole or into the second trench under the eave portion, and etching a side wall of the second hole or a side wall of the second trench with the etching gas.

2. The method according to claim 1, wherein the forming of the second hole or the second trench and the etching of the side wall of the second hole or the side wall of the second trench are performed inside a same etching processing chamber.

3. The method according to claim 1, wherein the eave portion is formed when forming the second hole or the second trench in the layer.

4. The method according to claim 1, wherein the eave portion is formed by physically etching the mask layer after forming the second hole or the second trench in the layer.

5. The method according to claim 1, wherein the side wall of the second hole is etched by the etching gas from all directions while a holder configured to hold the etching object is rotated when supplying the etching gas including the obliquely-incident ions into the second hole.

6. The method according to claim 1, wherein the side wall of the second trench is etched by the etching gas along one direction while a holder configured to hold the etching object is fixed when supplying the etching gas including the obliquely-incident ions into the second trench.

7. The method according to claim 1, wherein an incident angle of the ions incident inside the second hole or inside the second trench oscillates periodically.

8. The method according to claim 7, wherein a maximum value of the incident angle is within the range of 1° to 10°.

9. The method according to claim 1, wherein a first electrode is facing to the layer, and the etching gas in a plasma state is generated between the layer and the first electrode.

10. The method according to claim 9, wherein a first alternating current voltage, a second alternating current voltage, and a third alternating current voltage are applied to a second electrode of a holder configured to hold the etching object, frequencies of the second alternating current voltage and the third alternating current voltage being lower than a frequency of the first alternating current voltage.

11. The method according to claim 10, wherein
a first electrode element and a second electrode element are used as the second electrode, and
the first electrode element and the second electrode element are disposed alternately along a major surface of the layer.

12. The method according to claim 11, wherein the first alternating current voltage and the second alternating current voltage are applied to the first electrode element, and the first alternating current voltage and the third alternating current voltage are applied to the second electrode element.

13. The method according to claim 12, wherein the frequencies of the second alternating current voltage and the third alternating current voltage are substantially same with each other.

14. The method according to claim 10, wherein the first alternating current voltage is used to generate plasma of the etching gas.

15. The method according to claim 14, wherein the second alternating current voltage and the third alternating current voltage are used to attract the ions inside the plasma toward the etching object.

16. The method according to claim 12, wherein the second alternating current voltage and the third alternating current voltage are controlled to be applied with a phase difference between the second alternating current voltage and the third alternating current voltage when etching the side wall of the second hole or the side wall of the second trench.

17. The method according to claim 12, wherein the second alternating current voltage and the third alternating current voltage are controlled to be applied without a phase difference between the second alternating current voltage and the third alternating current voltage when forming the second hole or the second trench.

18. The method according to claim 4, wherein the mask layer is formed using a material selected from carbon and silicon oxide.

19. The method according to claim 18, wherein an etching gas selected from argon, a gas mixture of carbonyl sulfide and oxygen, and nitrogen is used when performing the physical etching of the mask layer.

20. The method according to claim 1, wherein the layer includes a conductive layer and an insulating layer stacked alternately in the layer.
